(19) United States
(12) Patent Application Publication
(10) Pub. No.: US 2021/0333841 A1
(43) Pub. Date: Oct. 28, 2021

(54) DISPLAY SCREEN AND DISPLAY DEVICE

(71) Applicant: WUHAN CHINA STAR OPTOELECTRONICS TECHNOLOGY CO., LTD., Wuhan (CN)

(72) Inventor: Mingjuan Li, Wuhan (CN)

(73) Assignee: WUHAN CHINA STAR OPTOELECTRONICS TECHNOLOGY CO., LTD., Wuhan (CN)

(21) Appl. No.: 16/344,055

(22) PCT Filed: Jan. 7, 2019
(86) PCT No.: PCT/CN2019/070622

§ 371 Date: Apr. 23, 2019

(30) Foreign Application Priority Data
Nov. 30, 2018 (CN) 201811458807.4

(51) Int. Cl. G06F 1/16; G06F 1/18; G09F 9/33; G09F 9/35

(52) U.S. Cl. CPC G06F 1/1684; G09F 9/35; G09F 9/335; G06F 1/183

(57) ABSTRACT

This disclosure provides a display screen and a display device, including a display area, a non-display area surrounding the display area and including a first non-display area and a second non-display area, a pre-sensor, a flexible circuit board being connected to an end of the display screen, and at least one IC chip being disposed in the first non-display area and being connected with the flexible circuit board. The IC chip or a COF structure is inverted and is set on the first non-display area, so as to realize a narrow border and increase the screen proportion.

### BACKGROUND OF THE INVENTION

### 1. Field of the Invention

This disclosure relates to a display technical field, and more particularly to a display screen and a display device.

### 2. Description of the Prior Art

With the wide application of a display screen and the high demand of users for diversified shapes and full screen experience of the display screen, the display screen with a special-shaped structure is increasingly replacing a traditional square display. However, the special-shaped structure will not only make a lower border of the display screen wider for disposing IC (Integrated Circuit) chips or COF (chip on film) on the lower border, but also make an upper border wider for disposing the special-shaped structure. This reduces a screen proportion of the display screen, thus affecting the user's full screen experience.

Hence, it needs to provide a new display screen and a display device thereof to solve above technical problems.

### 3. Technical Problem

The disclosure provides a display screen and a display device thereof, which solve the technical problem that a special-shaped structure of the display screen can not only make a lower border of the display screen wider for disposing IC chips or COF, but also make an upper border wider for disposing the special-shaped structure.

### BRIEF SUMMARY OF THE INVENTION

### Technical Solutions

To solve the above problems, the technical scheme provided by the embodiment of the disclosure is as follows:

The embodiment of this disclosure provides a display screen, including:

a display area;

a non-display area, surrounding the display area and including a first non-display area and a second non-display area, the first non-display area being located on two sides of the second non-display area;

a pre-sensor, being disposed in the second non-display area;

a flexible circuit board, being connected to an end of the display screen; and

at least one IC chip, being disposed in the first non-display area and being connected with signal lines of the flexible circuit board to drive the display screen.

According to the display screen provided by the embodiment of the disclosure, the first non-display area and the second non-display area are located on a top of the display screen.

According to the display screen provided by the embodiment of the disclosure, the non-display area further includes a third non-display area, which is located on two opposite sides of the display screen and on a lower border of the display screen.

According to the display screen provided by the embodiment of the disclosure, the IC chip is disposed on the two sides of the second non-display area.

According to the display screen provided by the embodiment of the disclosure, the IC chip is disposed on any one side of the second non-display area.

According to the display screen provided by the embodiment of the disclosure, a length of the IC chip is less than a length of one single edge of the corresponding first non-display area.

According to the display screen provided by the embodiment of the disclosure, a shape of the second non-display area can be one of triangles, polygons and circles.

According to the display screen provided by the embodiment of the disclosure, the IC chip is disposed on the flexible circuit board to form a COF package.

According to the display screen provided by the embodiment of the disclosure, the display screen further includes an ACF, and the IC chip is connected with the flexible circuit board through the ACF.

The embodiment of this disclosure provides a display device, comprising the above display screen.

### Beneficial Effect

The beneficial effects of the disclosure are as follows. The display screen and the display device provided in the embodiments of the present disclosure invert the IC chip or the COF structure, which is originally set in the lower border thereof, and set it on the first non-display area of the upper border thereof, so as to realize a narrow border of the lower border of the display screen and further increase the screen proportion.

### BRIEF DESCRIPTION OF THE DRAWINGS

For more clearly illustrating the technical scheme in the embodiment of the disclosure, the following text will briefly introduce the accompanying drawings used in the preferred embodiment. It is obvious that the accompanying drawings in the following description are only some embodiments of the present application. For the technical personnel of the field, other drawings can also be obtained from these drawings without paying creative work.

FIGS. 1A to 1F are structure schematic views of a display screen provided by embodiment 1 of the disclosure;

FIGS. 2A to 2F are structure schematic views of a display screen provided by embodiment 2 of the disclosure; and

FIG. 3 is a section view of a display device provided by embodiment 3.

### DETAILED DESCRIPTION OF THE PREFERRED EMBODIMENTS

The following description of every embodiment with reference to the accompanying drawings is used to exemplify a specific embodiment, which may be carried out in the disclosure. Directional terms mentioned in the disclosure, such as “upper”, “lower”, “front”, “back”, “left”, “right”, “inside”, “outside”, “side” etc., are only used with reference to the orientation of the accompanying drawings. Therefore, the used directional terms are intended to illustrate, but not to limit, the disclosure. In the figure, units with similar structures are represented by the same label.

The disclosure can solve the defect of a display screen and a display device of the prior art, that a special-shaped structure of the prior display screen can not only make a lower border of the display screen wider for disposing IC chips or COF thereon, but also make an upper border wider for disposing the special-shaped structure thereon.

### Embodiment 1

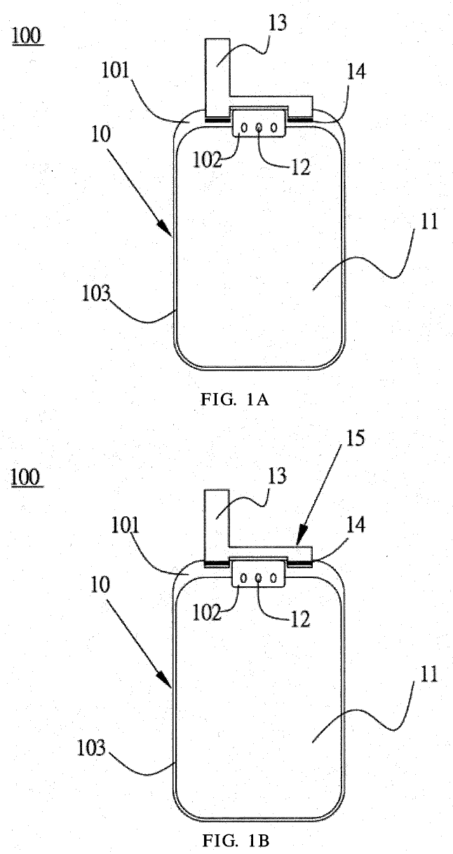

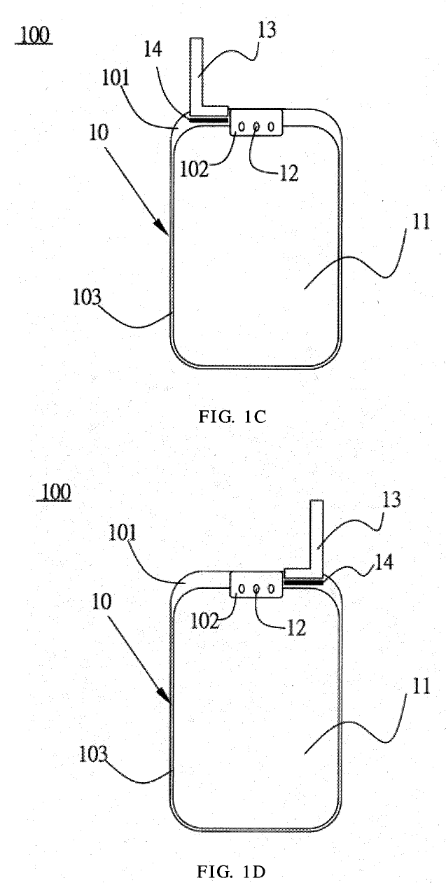

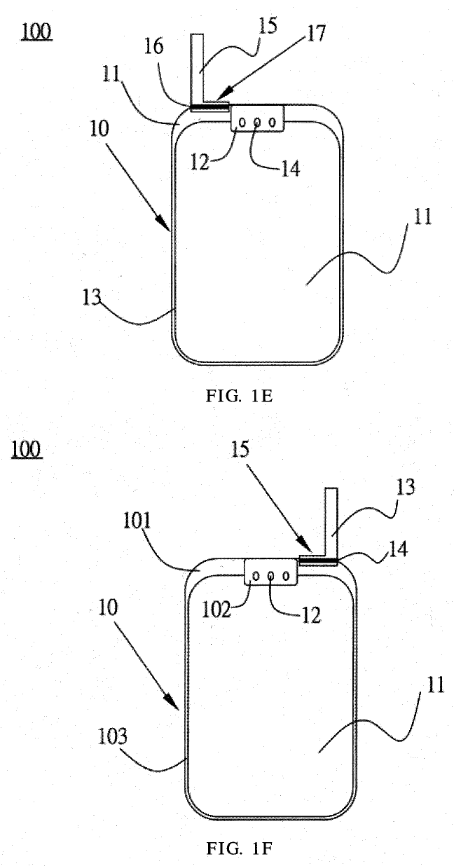

Referring to FIG. 1A, a display screen provided in the embodiment has a special-shaped structure being notch type. The display screen 100 provided in the embodiment includes:

a display area 11;

a non-display area 10, surrounding the display area 11; wherein the non-display area 10 includes a first non-display area 101 and a second non-display area 102, the first non-display area 101 is located on two sides of the second non-display area 102, and the first non-display area and the second non-display area are located on the top of the display screen;

a pre-sensor 12, being disposed in the second non-display area 102;

a flexible circuit board 13, being connected to an end of the display screen 100; and

at least one IC chip 14, being mounted in the first non-display area 101 and being connected with signal lines of the flexible circuit board 13 to drive the display screen 100.

Moreover, the non-display area further includes a third non-display area 103, which is located on two opposite sides of the display screen 100 and on a lower border of the display screen 100.

Wherein, the flexible circuit board 13 is connected to the end of the display screen 100. For example, one part of the flexible circuit board 13 is connected to a pad position in the first non-display area 101 of the display screen 100. The IC chip 14 can be directly mounted on a substrate in the first non-display area 101, and be connected with the signal lines of the flexible circuit board 13. The IC chip 14 is used to drive the display screen. A control signal generated by a driving circuit board (not shown in Figures) can be supplied to the IC chip 14 through the flexible circuit board 13. The IC chip 14 can transmit a drive signal to a display panel of the display screen 100. Specifically, it can transmit a signal for displaying an image to a pixel. The IC chip 14 can be a scan driver circuit or a data driver circuit. Wherein, the scan driver circuit may generate scan signals, and the data driver circuit may generate date signals.

In order to cater to usage habits of users, the second non-display area 102 of the embodiment is generally located on a middle of an upper border of the display screen 100. That is, the first non-display area 101 located on the two sides of the second non-display area 102 has two equal-length single edges. The pre-sensor 12 is disposed in the second non-display area 102. The pre-sensor 12 may be an optical sensor, which is convenient for users to take pictures with the optical sensor.

When a length of the second non-display area 102 is larger, and a length of the single edge of the first non-display area 101 is less than a length of a single IC chip, multiple IC chips 14 of smaller lengths can be used to replace the original single IC chip. Specifically, the first non-display area 101 disposes at least one IC chip 14 of smaller length on each of the two sides of the second non-display area 102 to drive the display panel. The length of the IC chip 14 of smaller length is less than the length of the single edge of the corresponding first non-display area 101, so that the single edge of the first non-display area 101 can accommodate the IC chip 14 of smaller length.

Referring to FIG. 1B, the IC chip 14 of smaller length may be installed on the flexible circuit board 13 in addition to being directly installed on the substrate of the first non-display area 101. Now, the flexible circuit board 13 containing the IC chip 14 of smaller length forms a COF package 15. The IC chip 14 is bonded with the flexible circuit board 13 through an ACF (Anisotropic Conductive Film), thereby completing the packaging of the IC chip 14. Then the COF package 15 is placed in the first non-display area 101 located on the two opposite sides of the second non-display area 102. A width of the upper border can be effectively reduced by using the COF packaging method, thereby increasing a screen proportion of the display screen 100.

Referring to FIGS. 1C and 1D, when the length of the second non-display area 102 is smaller, and the length of the single edge of the first non-display area 101 is greater than the length of the original single IC chip 14, the single edge of the first non-display area 101 can totally accommodate the single IC chip 14. Therefore, optionally, the single IC chip 14 can be installed on any one single edge of the first non-display area 101. Namely, the single IC chip 14 can be installed on any side of the second non-display area 102. Referring to FIG. 1C, the single IC chip 14 is installed on the first non-display area 101 located on a left side of the second non-display area 102. Referring to FIG. 1D, the single IC chip 14 is installed on the first non-display area 101 located on a right side of the second non-display area 102.

Referring to FIGS. 1E and 1F, similarly, the single IC chip 14 can also be disposed on the flexible circuit board 13 by using the COF packaging method, so the flexible circuit board 13 containing the single IC chip 14 forms the COF package 15, and then the COF package 15 is placed on any one single edge of the first non-display area 101. Wherein, FIG. 1E shows that the COF package 15 is placed on the first non-display area 101 located on a left side of the second non-display area 102, and FIG. 1F shows that the COF package 15 is placed on the first non-display area 101 located on a right side of the second non-display area 102.

The display screen 100 provided in the embodiment can be a liquid crystal display or an organic light emitting display. In the embodiment, the first non-display area of the display screen 100 has a fan-out line, one end of which is connected with the IC chip 14, and the other end of which is electrically connected with multiple scanning lines of the display area 11. The IC chip 14 can provide scanning signals for the scanning lines through the fan-out line. The flexible circuit board 13 is electrically connected to bonding terminals on the first non-display area 101 through the ACF. The position of the bonding terminals is corresponding to the position of the flexible circuit board 13. For example, when the first non-display area 101 is provided with at least one IC chip 14 of smaller length on each of the two sides of the second non-display area 102, the bonding terminals are disposed on the first non-display area 101 located on each of the two sides of the second non-display area 102. When the IC chip 14 is disposed on any one single edge of the first non-display area 101, the bonding terminals are disposed on the corresponding single edge of the first non-display area 101. Moreover, the arrangement of the fan-out line can also change accordingly.

### Embodiment 2

Since the special-shaped structure of the display screen may be one of triangles, polygons and circles, the circles here may include ellipses, quasi-circles, etc., and the polygons here may include rectangles or other polygons, etc., that is to say, the second non-display area may be of various shapes. The shape of the second non-display area may depend on the shape of the pre-sensor placed and the requirement of the screen proportion of the display screen to be set. In the embodiment, the shape of the second non-display area can be notch type or water drop type.

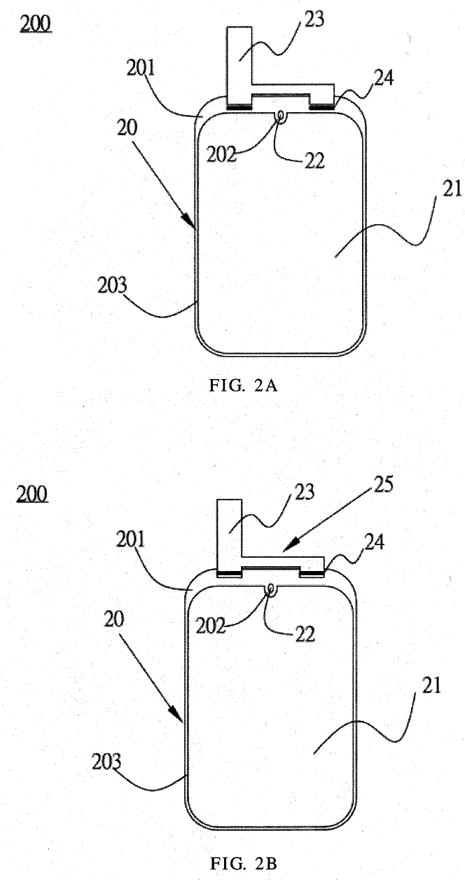

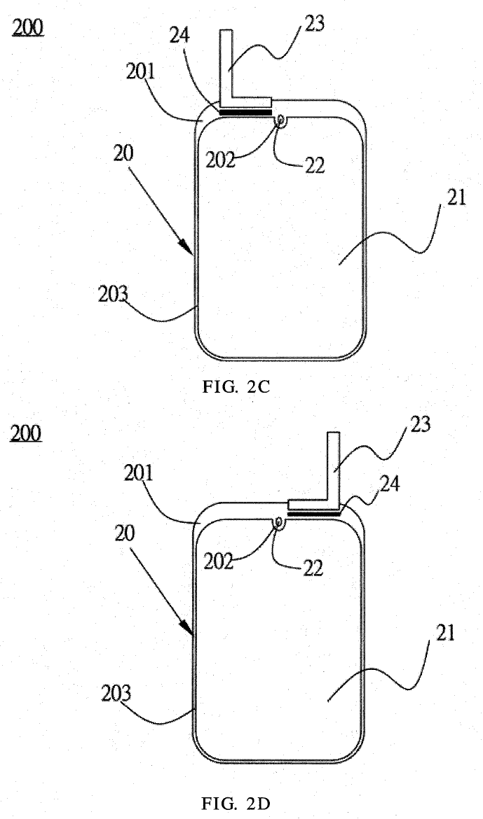

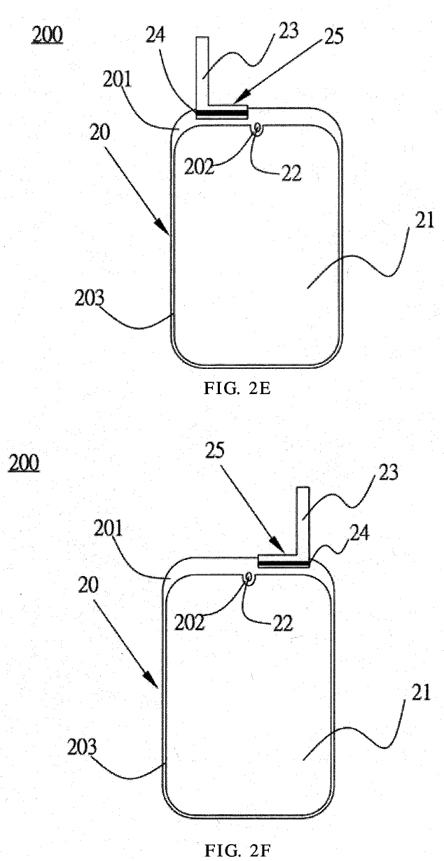

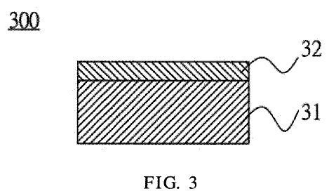

Referring to FIG. 2A, the special-shaped structure of the display screen 200 provided in the embodiment is water drop type. The display screen 200 provided in the embodiment includes:

a display area 21;

a non-display area 20, surrounding the display area 21; wherein the non-display area 20 includes a first non-display area 201 and a second non-display area 202, the first non-display area 201 is located on two sides of the second non-display area 202, and the first non-display area 201 and the second non-display area 202 are located on the top of the display screen;

a pre-sensor 22, being disposed in the second non-display area 202;

a flexible circuit board 23, being connected to an end of the display screen 200; and

at least one IC chip 24, being mounted in the first non-display area 201 and being connected with signal lines of the flexible circuit board 23 to drive the display screen 200.

Moreover, the non-display area further includes a third non-display area 203, which is located on two opposite sides of the display screen 200 and on a lower border of the display screen 200.

The display screen 200 with the special-shaped structure of water drop type provided in embodiment 2 is similar to the display screen 100 with the special-shaped structure of notch type provided in embodiment 1. The difference of them is that, a length of the second non-display area 202 in embodiment 2 is less than that of the second non-display area 102 of the display screen 100 in embodiment 1. Therefore, a length of the first non-display area 201 is greater than that of the first non-display area 101 of the display screen 100.

Referring to FIG. 2A, as in embodiment 1, when a length of one single edge of the first non-display area 201 is less than a length of a single IC chip, multiple IC chips 24 of smaller lengths can be used to replace the original single IC chip. Specifically, the first non-display area 201 disposes at least one IC chip 24 of smaller length on each of the two sides of the second non-display area 202 to drive a display panel. The length of the IC chip 24 is less than the length of the single edge of the corresponding first non-display area 201, so that the single edge of the first non-display area 201 can accommodate the IC chip 24.

Referring to FIG. 2B, the IC chip 24 of smaller length may be installed on the flexible circuit board 23 in addition to being directly installed on a substrate of the first non-display area 201, so that the flexible circuit board 23 containing the IC chip 24 of smaller length forms a COF package 25. The IC chip 24 is bonded with the flexible circuit board 23 through an ACF (Anisotropic Conductive Film), thereby completing the packaging of the IC chip 24. Then the COF package 25 is placed in the first non-display area 201 located on the two opposite sides of the second non-display area 202. A width of the upper border can be effectively reduced by using the COF packaging method, thereby increasing a screen proportion of the display screen 200.

Because the length of the first non-display area 201 in the embodiment is greater than that of the first non-display area 101 in embodiment 1, it is easier for the display screen 200 described in the embodiment to place the IC chip 24 on any one single edge of the first non-display area 201 than the display screen 100 provided in embodiment 1. Therefore, when the length of the second non-display area 202 is smaller and the length of the single edge of the first non-display area 201 is greater than the length of the original single IC chip 24, the IC chip 24 can optionally be installed on any one single edge of the first non-display area 201. Namely, the IC chip 24 can be installed on any side of the second non-display area 202.

Referring to FIG. 2C, the single IC chip 24 is installed on the first non-display area 201 located on a left side of the second non-display area 202. Referring to FIG. 2D, the single IC chip 24 is installed on the first non-display area 201 located on a right side of the second non-display area 202.

Referring to FIGS. 2E and 2F, similarly, the single IC chip 24 can also be disposed on the flexible circuit board 23 by using the COF packaging method, so the flexible circuit board 23 containing the single IC chip 24 forms the COF package 25, and then the COF package 25 is placed on any one single edge of the first non-display area 201. Wherein, FIG. 2E shows that the COF package 25 is placed on the first non-display area 201 located on a left side of the second non-display area 202, and FIG. 1F shows that the COF package 25 is placed on the first non-display area 201 located on a right side of the second non-display area 202.

The display screen 200 provided in the embodiment can be a liquid crystal display or an organic light emitting display. In the embodiment, the first non-display area of the display screen 200 has a fan-out line, one end of which is connected with the IC chip 24, and the other end of which is electrically connected with multiple scanning lines of the display area 21. The IC chip 24 can provide scanning signals for the scanning lines through the fan-out line. The flexible circuit board 23 is electrically connected to bonding terminals on the first non-display area 201 through the ACF. The position of the bonding terminals is corresponding to the position of the flexible circuit board 23. For example, when the first non-display area 201 is provided with at least one IC chip 24 of smaller length on each of the two sides of the second non-display area 202, the bonding terminals are disposed on the first non-display area 201 located on each of the two sides of the second non-display area 202. When the IC chip 24 is disposed on any one single edge of the first non-display area 201, the bonding terminals are disposed on the corresponding single edge of the first non-display area 201. Moreover, the arrangement of the fan-out line also changes accordingly.

### Embodiment 3

Referring to FIG. 3, the disclosure further provides a display device 300, including a backlight module 31 and a display screen 32 disposed on the backlight module 31. The display screen 32 can adopt the display screen described in above embodiments. The display device can be used for mobile phones or various electronic devices, such as smart tablet computers, e-book readers, MP3 (Moving Picture Experts Group Audio Layer III) players, MP4 (Moving Picture Experts Group Audio Layer IV) players, laptop portable computers and desktop computers, etc. The display device provided in the embodiment has a greater screen proportion.

The beneficial effects of the disclosure are as follows. The display screen and the display device provided in the embodiments of the present disclosure invert the IC chip or the COF structure, which is originally set in the lower border, and set it on the first non-display area of the upper border, so as to realize a narrow border of the lower border of the display screen and further increase the screen proportion.

As described above, the disclosure has been described by the preferred embodiments, but the above preferred embodiments are not used to limit the disclosure. The person skilled in the art may make various changes and embellishments without departing from the spirit and scope of the present disclosure, so the scope of protection disclosed herein shall be subject to the scope defined by the claims.

What is claimed is:

1. A display screen, which has a special-shaped structure being notch type, the display screen including:
a display area;
a non-display area, surrounding the display area and including a first non-display area and a second non-display area, the first non-display area being located on two sides of the second non-display area;
a pre-sensor, being disposed in the second non-display area;
a flexible circuit board, being connected to an end of the display screen; and
at least one IC chip, being disposed in the first non-display area and being connected with signal lines of the flexible circuit board to drive the display screen.

2. The display screen as claimed in claim 1, wherein the first non-display area and the second non-display area are located on a top of the display screen.

3. The display screen as claimed in claim 1, wherein the non-display area further includes a third non-display area, which is located on two opposite sides of the display screen and on a lower border of the display screen.

4. The display screen as claimed in claim 1, wherein the IC chip is disposed on the two sides of the second non-display area.

5. The display screen as claimed in claim 1, wherein the IC chip is disposed on any one side of the second non-display area.

6. The display screen as claimed in claim 4, wherein a length of the IC chip is less than a length of one single edge of the corresponding first non-display area.

7. The display screen as claimed in claim 1, wherein a shape of the second non-display area can be one of triangles, polygons and circles.

8. The display screen as claimed in claim 1, wherein the IC chip is disposed on the flexible circuit board to form a COF package.

9. The display screen as claimed in claim 8, wherein the display screen further includes an ACF, and the IC chip is connected with the flexible circuit board through the ACF.

10. A display screen, wherein the display screen includes:
a display area;
a non-display area, surrounding the display area and including a first non-display area and a second non-display area, the first non-display area being located on two sides of the second non-display area;
a pre-sensor, being disposed in the second non-display area;
a flexible circuit board, being connected to an end of the display screen; and
at least one IC chip, being disposed in the first non-display area and being connected with signal lines of the flexible circuit board to drive the display screen.

11. The display screen as claimed in claim 10, wherein the first non-display area and the second non-display area are located on a top of the display screen.

12. The display screen as claimed in claim 10, wherein the non-display area further includes a third non-display area, which is located on two opposite sides of the display screen and on a lower border of the display screen.

13. The display screen as claimed in claim 10, wherein the IC chip is disposed on the two sides of the second non-display area.

14. The display screen as claimed in claim 10, wherein the IC chip is disposed on any one side of the second non-display area.

15. The display screen as claimed in claim 13, wherein a length of the IC chip is less than a length of one single edge of the corresponding first non-display area.

16. The display screen as claimed in claim 10, wherein a shape of the second non-display area can be one of triangles, polygons and circles.

17. The display screen as claimed in claim 10, wherein the IC chip is disposed on the flexible circuit board to form a COF package.

18. The display screen as claimed in claim 17, wherein the display screen further includes an ACF, and the IC chip is connected with the flexible circuit board through the ACF.

19. The display screen as claimed in claim 10, wherein the display screen is a liquid crystal display or an organic light emitting display.

20. A display device, comprising a display screen as claimed in claim 10.
